(19) United States
(12) Patent Application Publication
(10) Pub. No.: US 2026/0214805 A1
(43) Pub. Date: Jul. 23, 2026

(54) METHODS AND APPARATUS TO APPLY LOAD TO A SOCKETED INTEGRATED CIRCUIT PACKAGE INDEPENDENT OF A HEATSINK LOADING MECHANISM

(71) Applicant: Intel Corporation, Santa Clara, CA (US)

(72) Inventors: James Trevor Goulding, Sherwood, OR (US); Jeffory L. Smalley, East Olympia, WA (US); Min Pei, Camas, WA (US); Eric W. Buddrius, Hillsboro, OR (US)

(73) Assignee: Intel Corporation, Santa Clara, CA (US)

(21) Appl. No.: 19/569,674

(22) Filed: Mar. 17, 2026

(51) Int. Cl. H05K 1/181; H05K 1/02; H10W 40/20; H10W 40/60

(52) U.S. Cl. CPC H05K 1/181; H05K 1/0203; H10W 40/233; H10W 40/611; H05K 2201/10325; H05K 2201/10393; H05K 2201/10409

(57) ABSTRACT

Systems, apparatus, articles of manufacture, and methods to apply load to a socketed integrated circuit package independent of a heatsink loading mechanism are disclosed. An example apparatus includes a load plate to interface with an integrated circuit package along a perimeter of the integrated circuit package while permitting a heatsink to interface with a central region of the integrated circuit package; and a torsion spring carried by the load plate. The torsion spring is on a first surface of the load plate. The integrated circuit package engages a second surface of the load plate, the second surface opposite the first surface. The torsion spring urges the load plate toward the integrated circuit package to provide a load to urge the integrated circuit package toward a socket on a circuit board.

### BACKGROUND

The demand for greater computing power and faster computing times continues to grow. This has led to higher-density connectors on computer hardware components to transfer signals more quickly. Some processor chips (e.g., land grid array (LGA) processor chips, ball grid array (BGA) processor chips, pin grid array (PGA) processor chips, etc.) are communicatively coupled to printed circuit boards (PCBs) via sockets constructed to receive and electrically couple to contacts on the processor chips. Often a heatsink is mechanically and thermally coupled to the processor chip on a side opposite the socket to facilitate the dissipation of heat generated by the processor chip. In some instances, the heatsink also provides a compressive load on the processor chip to ensure electrical connection between the chip and the associated socket.

### BRIEF DESCRIPTION OF THE DRAWINGS

FIG. 1 is an exploded view of an example integrated circuit (IC) package heat dissipating component stack constructed in accordance with teachings disclosed herein.

FIG. 2 is a partially exploded view of the example load plate and associated torsion spring assemblies shown in FIG. 1.

FIG. 3 is a top view of the example torsion spring shown in FIG. 2.

FIG. 4 is a side view of the example torsion spring shown in FIG. 2.

FIG. 5 is an end view of the example torsion spring shown in FIG. 2.

FIGS. 6 and 7 are cross-sectional views of the example component stack of FIG. 1 after assembly, but before the example spring loading assemblies have been tightened to apply a load to the example load plate.

FIGS. 8 and 9 are cross-sectional views similar to FIGS. 6 and 7 but showing the example component stack of FIG. 1 after the example spring loading assemblies have been tightened to apply a load to the example load plate.

FIG. 10 is a flowchart representative of an example method of manufacturing the example load plate with the torsion spring assemblies of FIG. 1-9.

FIG. 11 is a top view of a wafer including dies that may be included in an IC package constructed in accordance with teachings disclosed herein.

FIG. 12 is a cross-sectional side view of an IC device that may be included in an IC package constructed in accordance with teachings disclosed herein.

FIG. 13 is a cross-sectional side view of an IC package that may be used to implement the example IC package shown in FIGS. 1 and 6-9.

FIG. 14 is a cross-sectional side view of an IC device assembly that may include an IC package constructed in accordance with teachings disclosed herein.

FIG. 15 is a block diagram of an example electrical device that may include a component stack constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Integrated circuit (IC) packages, such as central processing units (CPUs), graphics processing units (GPUs) and/or other processor chips, are often coupled to printed circuit boards (PCBs) via sockets. Many sockets, including land grid array (LGA) sockets, include a plurality of pins that receive and electrically couple to corresponding features (e.g., contacts or lands) of the IC package. To ensure that the IC package is able to communicate with the circuit board, the pins of the socket must remain in contact with the IC package. In many instances, the contact force between the pins of the socket and the IC package is provided by one or more fasteners coupled between a heatsink (disposed on the IC package opposite the socket) and a backplate (disposed on an opposite side of the printed circuit board relative to the socket and the IC package). Such assemblies of components are referred to herein as IC package heat dissipating component stacks (or simply, component stacks for short). The fasteners that secure such component stacks together with sufficient compressive force to ensure electrical contact between the socket and IC package can cause warpage, bending, or deflection of the backplate, the printed circuit board, and/or other components in the component stack. Such deflection can reduce the contact force in particular areas of the socket.

In recent years, the pin count of sockets has increased to accommodate larger IC packages with more electrical contacts than have been used in the past. The increasing number of connections to be made between the pins of a socket and corresponding contacts on a package results in the need for an increased loading force to ensure a reliable connection. However, as the loading force (typically provided by the fasteners associated with a heatsink) increases, the amount of warpage, bending, and/or deflection in the backplate and/or other components also increases. This increase in deflection is exacerbated by the fact that the heatsink fasteners are farther apart than in the past due to the heatsink being larger to match the corresponding increase in size of larger IC packages.

Examples disclosed herein provide a spring-based loading mechanism that increases the load applied to an IC package independent of the heatsink fasteners. Moreover, the spring-based loading mechanism applies the separate load at locations closer to the center of the IC package than the loads provided by the heatsink fasteners (which are located adjacent to and beyond the corners of the package). As a result of the independent loading provided by the spring-based mechanism, examples disclosed herein enable the overall load on an IC package to increase relative to known techniques to ensure reliable electrical connection between the socket and the package. Inasmuch as the additional load from the spring-loaded mechanism is provided at locations closer to the center of the IC package than the loads provided by the heatsink fasteners, the additional load does not contribute to the bending or deflection of the backplate to the same extent as if the loads provided by the heatsink fasteners were to increase a corresponding amount. In other words, examples disclosed herein have the advantage of increasing the package loading force (needed for reliable electrical connections) while reducing (e.g., avoiding) the deleterious effects of a corresponding increase in bending or deflection of the backplate.

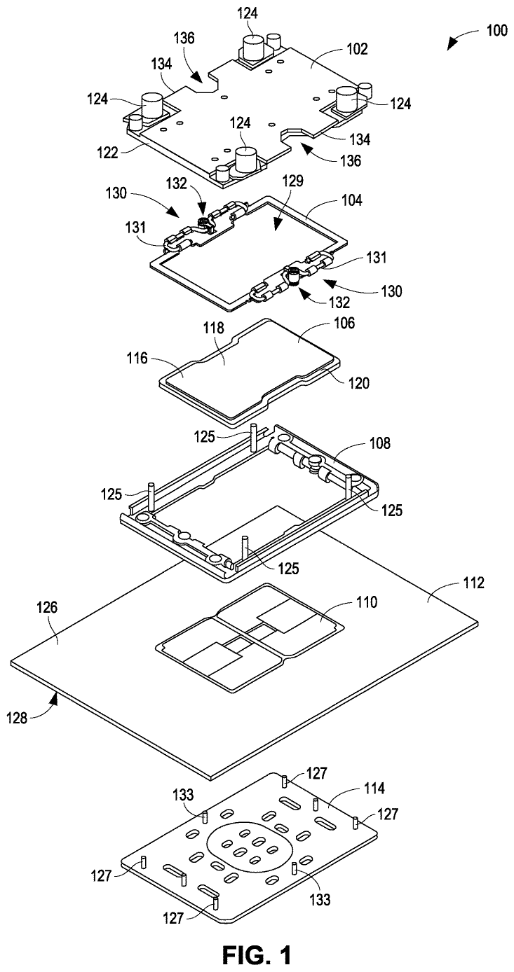

FIG. 1 illustrates an exploded view of an example integrated circuit (IC) package heat dissipating component stack 100 (also referred to simply as a “component stack” for short) constructed in accordance with teachings disclosed herein. In FIG. 1, the component stack 100 includes a heatsink 102, a load plate 104, an integrated circuit (IC) package 106, a bolster plate 108, a socket 110 coupled to a printed circuit board (PCB) 112 (e.g., a motherboard), and a backplate 114.

The IC package 106 includes one or more electrical circuits on a semiconductor substrate. The IC package 106 can perform processing functions, memory functions, and/or any other suitable functions. The IC package 106 can include any type of processing circuitry, including programmable microprocessors, one or more FPGAs, one or more CPUs, one or more GPUs, one or more DSPs, one or more XPUs, one or more ASICs, and/or one or more microcontrollers. In this example, the IC package 106 is a land grid array (LGA) processor chip. In other examples, the IC package 106 is a ball grid array (BGA) processor chip or a pin grid array (PGA) processor chip. Further, other types of IC packages can be used in the component stack 100 instead of a processor chip (e.g., a memory chip).

As shown in the illustrated example, the IC package 106 includes an integrated heat spreader (IHS) 116 with a large central region 118 and a recessed shoulder 120 (e.g., rim, edge) that extends around the perimeter or periphery of the IC package 106. In this example, the shoulder 120 extends entirely around the periphery. In other examples, the shoulder 120 is provided along less than the entire periphery. In some examples, the shoulder 120 is omitted.

In this example, the heatsink 102 includes a base 122 that is to support an array of fins to facilitate the dissipation of heat. For purposes of illustration, the fins are omitted in FIG. 1. In some examples, the heatsink 102 is couplable (e.g., thermally couplable) to the IC package 106 to dissipate heat therefrom. More particularly, in some examples, the base 122 thermally couples with the central region 118 of the IHS 116 of the package 106.

In the illustrated example of FIG. 1, the heatsink 102 is mechanically coupled to the backplate 114 via fasteners 124 (e.g., fixture elements, loading mechanisms). In some examples, the heatsink 102 is coupled to the backplate 114 with the bolster plate 108 positioned therebetween. More particularly, in some examples, the fasteners 124 on the heatsink 102 engage with first posts 125 on the bolster plate 108 that is couplable to a top surface 126 of the PCB 112 (e.g., around the socket 110 that is also on the top surface 126 of the PCB). Further, the bolster plate 108 engages with second posts 127 on the backplate 114 that is couplable to a bottom surface 128 of the PCB 112 opposite the bolster plate 108. In this manner, the PCB 112 is sandwiched between the bolster plate 108 and the backplate 114 with the heatsink 102 directly connected to the bolster plate 108. Based on this arrangement, tightening of the fasteners 124 places the components between the heatsink 102 and the backplate 114 within the component stack 100 in compression. In particular, as the heatsink 102 is urged towards the backplate 114, the heatsink 102 presses the IC package 106 towards the socket 110.

In this example, the socket 110 communicatively couples the IC package 106 to the PCB 112. In some examples, the socket 110 is a land grid array (LGA) socket, which includes a plurality of pins within the socket arranged to interface (e.g., electrically couple) with corresponding contacts or lands on the IC package 106. In other examples, the socket 110 can be implemented by any other suitable type of socket (e.g., a ball grid array, a pin grid array, etc.) suitable to receive and interface with the IC package 106. The compression created by the mechanical coupling of the heatsink 102 to the backplate 114 via the fasteners 124 serves to ensure that corresponding connectors (e.g., pins, lands, etc.) on the socket 110 and the IC package 106 remain in contact.

As noted above, as IC packages increase in size and include a larger pin count, there is a need for an increased loading force. However, increasing the loading force can be problematic because such an increase results in greater warpage, bending, or deflection of the backplate 114. The warpage or deflection of the backplate 114 arises because the loading force on the IC package 106 is provided by the fasteners 124 on the heatsink 102, which are spaced relatively far apart near the corners of the component stack 100. Moreover, the space between the fasteners 124 is greater for larger IC packages, thereby exacerbating the problem of deflection in the backplate 114. The example component stack 100 of FIG. 1 mitigates against these problems by providing additional load forces on the IC package 106 that are independent of the loading created by the fasteners 124 on the heatsink 102. Furthermore, the locations where these additional forces are applied on the IC package 106 are distinct and spaced apart from the corners where the loading from the fasteners 124 is created. These additional load forces are provided via the example load plate 104.

In some examples, the load plate 104 is fabricated from a sheet of metal (e.g., 300 series stainless steel). In the illustrated example of FIG. 1, the load plate 104 includes an opening 129 dimensioned to fit around the central region 118 of the IHS 116 and engage with the shoulder 120 of the IHS 116. Thus, the load plate 104 is an example of means for engaging with a surface of the IC package 106. In some examples, the load plate 104 is dimensioned to engage with the full length of the shoulder 120 (e.g., along the entire perimeter or periphery of the package 120 in FIG. 1). In other examples, the load plate 104 includes one or more tabs or protrusions that engage corresponding portion(s) of the shoulder 120 while other portion(s) of the shoulder 120 remain uncovered by the load plate 104. In some examples, the load plate 104 has a thickness that is equal to or less than the difference in height between the central region 118 and the shoulder 120 of the IHS 116 so that the load plate 104 can engage with the shoulder 120 without interfering with the thermal coupling of the heatsink 102 and the central region 118 of the IHS 116. In other examples, the bottom side of the base 122 of the heatsink 102 includes cutouts and/or cavities that allow space for the load plate 104 to extend above the central region 118 (and/or to enable the load plate 104 to engage the top surface of the central region 118).

As shown in the illustrated example, the load plate 104 includes and/or carries two torsion spring assemblies 130. Each torsion spring assembly includes a torsion spring 131 (e.g., means for storing torque) that can be selectively loaded or released using a spring loading assembly 132 (e.g., means for loading the torsion spring 131). More particularly, the torsion spring is loaded by tightening engagement of the spring loading assembly 132 with third posts 133 on the backplate 114. In some examples, the third posts 133 are additionally or alternatively provided on the bolster plate 108. When the torsion spring 131 is loaded by the spring loading assembly 132, the torsion spring 131 produces a force on the load plate 104 that is transferred to the shoulder 120 of the IHS 116 on the IC package 106. As a result, the torsion spring assemblies 130 are capable of urging the load plate 104 towards the IC package 106 to produce a load acting on the IC package 106 that urges the package towards the socket 110. Thus, the torsion spring assemblies 130 are example means for urging the load plate 104 towards the IC package 106.

Experimental modelling has confirmed the viability of examples disclosed herein. Specifically, in some modeled examples, a deflection of the moment arm 206 by 2 millimeters produces approximately 100 pounds of force on the IC package 106. Larger or smaller forces may be achieved based on different constructions of the torsion spring 131 adapted for any suitable application. That is, variations in design of the torsion spring 131 enable load forces on the IC package 106 to be tuned at a lower spring constant with a longer load path than is possible using the fasteners 124 that are relied on to provide the entire loading force in known component stacks. As a result, examples disclosed herein provide for better compensation for tolerance in other parts of the loading path.

In this example, the torsion spring assemblies 130 are positioned between the fasteners 124 of the heatsink 102. As such, the load forces produced by the torsion spring assemblies 130 are located closer to the center of the IC package 106 than the loads from the fasteners 124 are to the center of the IC package 106. Therefore, the load forces produced by the torsion spring assemblies 130 result in less deflection of the backplate 114 while still providing added loading force to facilitate the connection between the IC package 106 and the socket 110.

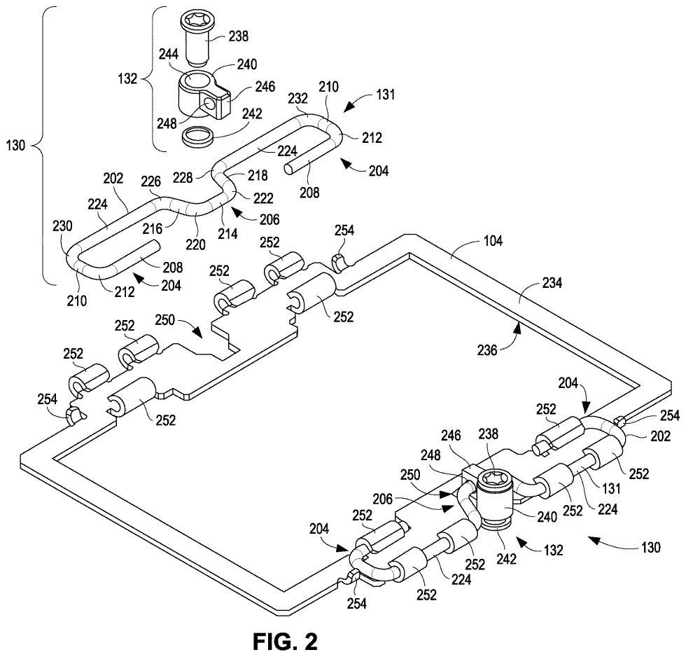

Although the example load plate 104 of FIG. 1 shows two torsion spring assemblies 130, any other suitable number (e.g., 1, 2, 3, 4, 5, 6, etc.) may be used. Further, in some examples, the torsion spring assemblies 130 can be different sizes (larger or smaller) and/or different shapes than what is shown in FIG. 1. Further still, in some examples, the torsion spring assemblies 130 can be at different locations than what is shown in FIG. 1. For instance, in this example, the torsion spring assemblies 130 are located along the long sides of the load plate 104. In other examples, the torsion spring assemblies 130 are located along the short sides of the load plate 104. In other examples, at least one torsion spring assembly 130 is located along a long side of the load plate 104 while at least one other torsion spring assembly 130 is located along a short side. In some examples, at least two torsion spring assemblies 130 are located along the same side of the load plate 104. Further details relating to the construction and operation of the load plate 104 and torsion spring assemblies 130 are provided below in connection with FIGS. 2-9.

In some examples, the sides 134 of the base 122 of the heatsink 102 (that are aligned with the torsion spring assemblies 130) are thinner than other portions of the base 122 to provide space or clearance for the torsion springs 131 positioned between the load plate 104 and the heatsink 102. Further, in some examples, the base 122 of the heatsink 102 includes cutouts 136 aligned with the spring loading assemblies 132 of the torsion spring assemblies 130. The cutouts 136 provide access to the spring loading assemblies 132 after the component stack 100 has been assembled to enable the tightening and/or loosening of the spring loading assemblies 132 to load and/or unload the torsion springs 131.

FIG. 2 is a partially exploded view of the example load plate 104 and associated torsion spring assemblies 130 shown in FIG. 1. More particularly, in the illustrated example of FIG. 2, one of the torsion spring assemblies 130 is shown in an exploded view while the other torsion spring assembly 130 is shown in an assembled view. In this example, the torsion spring 131 associated with each of the torsion spring assemblies 130 is fabricated from a length of metal wire 202 (e.g., music wire) that has been bent into a particular shape. In this example, the particular shape of the torsion spring 131 includes two support sections 204 at opposing ends of the wire 202 and a moment arm 206 at the middle of the wire 202. As shown in the illustrated example, each of the support sections 204 is defined by first and second straight segments 208, 210 with a first bend 212 therebetween. In this example, the first and second straight segments 208, 210 and the first bend 212 result in the support sections 204 having a hook shape. In other examples, the first bend 212 of at least one of the support sections 204 bends in the opposite direction to what is shown so that the corresponding first segment 208 extends away from the moment arm 206 rather than towards the moment arm 206 as shown. As shown in the illustrated example, the moment arm 206 is defined by third, fourth, and fifth straight segments 214, 216, 218 separated by third and fourth bends 220, 222. The example torsion spring 131 also includes two torsion segments 224 corresponding to additional straight segments of the wire 202 that extend between and couple the moment arm 206 to respective ones of the support sections 204. More particularly, as shown in the illustrated example, either side of the moment arm 206 is coupled to inward facing ends of the torsion segments 224 via corresponding fourth and fifth bends 226, 228. Further, each support section 204 is coupled to an outward facing end of one of the torsion segments 224 via corresponding sixth and seventh bends 230, 232.

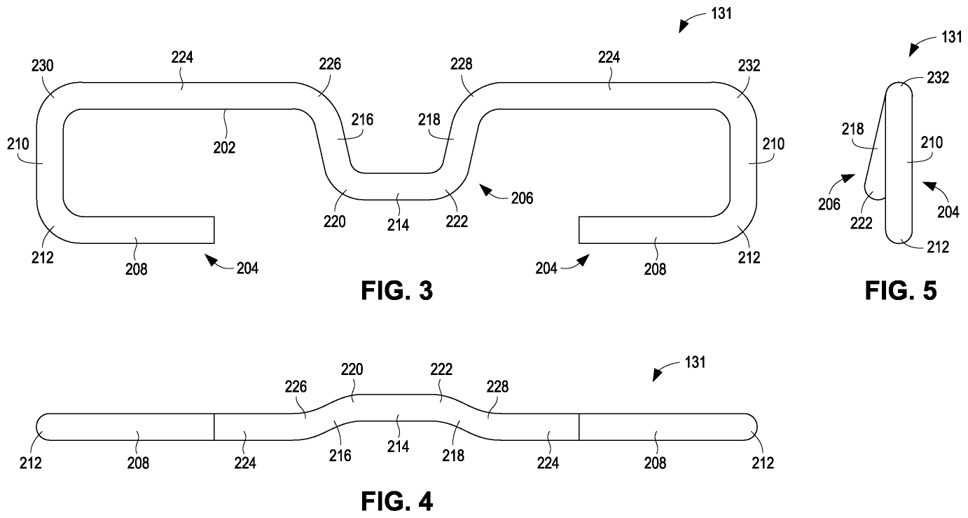

Enlarged views of the torsion spring 131 are shown in FIGS. 3-5. Specifically, FIG. 3 is a top view of the example torsion spring 131, FIG. 4 is a side view of the example torsion spring 131, and FIG. 5 is an end view of the example torsion spring 131. In this example, the two torsion segments 224 are aligned (e.g., colinear) so that torsion forces (e.g., torque) can be created along both their lengths when the moment arm 206 is moved relative to the support sections 204 as discussed in further detail below. In some examples, the support sections 204 and/or the moment arm 206 include a different number (e.g., 0, 1, 2, 3, 4, 5, etc.) of straight segments and/or a different number (e.g., 0, 1, 2, 3, 4, 5, etc.) of bends from what is shown in the illustrated example. Further, in some examples, the lengths of the straight segments 208, 210, 214, 216, 218 (including the torsion segments 224), the angle of the bends 212, 220, 222, 226, 228, 230, 232, and/or the radius of curvature of the bends 212, 220, 222, 226, 228, 230, 232 can be different from what is shown in the illustrated example.

As shown in FIGS. 3-5, not all of the bends 212, 220, 222, 226, 228, 230, 232 (or the corresponding segments 208, 210, 214, 216, 218, 224) are in the same plane. That is, as shown in the illustrated example, the support sections 204 and the torsion segments 224 all lie within a common plane. However, the moment arm 206 is angled relative to the common plane of the support sections 204 and the torsion segments 224. In this example, the support sections 204 and the torsion segments 224 are in a common plane to lie flat on a first surface 234 of the load plate 104 (e.g., the upper surface that faces towards the heatsink 102 that is opposite a second (bottom) surface 236 that is to face towards and engage with the IC package 106). The moment arm 206 is angled relative to the plane defined by the support sections 204 and the torsion segments 224 in a direction extending away from the load plate 104. As a result of this arrangement, the moment arm 206 can be urged toward the load plate 104 while the support sections 204 remain fixed in place (because they are already against the first surface 234 of the load plate 104).

As shown in the illustrated example of FIG. 2, the spring loading assembly 132 includes a load nut 238, a load block 240, and a collar 242. In this example, the load nut 238 extends through a hole 244 in the load block 240. In some examples, the hole 244 is dimensioned to provide a clearance fit between the load nut 238 and the load block 240 so that the load nut 238 is free to rotate relative to the load block 240. In some examples, the collar 242 is affixed to the bottom end of the load nut 238 to retain the load nut 238 within hole 244 of the load block 240. The collar 242 can be affixed to the load nut 238 in any suitable manner (e.g., threaded, press fit, with an adhesive, etc.). In some examples, the collar 242 is omitted. In this example, the load nut 238 includes an internal bore that is threaded to engage with threads on third posts 133 protruding upwards from the backplate 114. In other examples, the load nut 238 is replaced by a load screw with external threads that engage with a threaded hole in at least one of the bolster plate 108 or the backplate 114. Thus, the load nut 238 (with internal threads) and a load screw (with external threads) are examples of means for threading.

As shown in the illustrated example, the load block 240 includes a radial protrusion 246 (e.g., tab) that has an opening 248 extending therethrough that is dimensioned to receive and engage with the moment arm 206 (e.g., the fourth straight segment 214) of the torsion spring 131. In this example, the opening 248 is a circular through-hole in the radial protrusion 246. In other examples, the opening 248 can be an oblong (e.g., elongated) slot and/or any other suitable shape. In other examples, the opening 248 is open at the bottom end of the radial protrusion 246 such that the radial protrusion 246 defines a hook-like structure that extends over and catches on to the moment arm 206 of the torsion spring 131.

In the illustrated example, as the load nuts 238 of the spring loading assemblies 132 are tightened around the corresponding third posts 133 associated with the backplate 114 (and/or the bolster plate 108), the load nuts 238 will move downward (e.g., toward the circuit board 112 of FIG. 1). This movement will force the load block 240 in the same direction, which will urge the moment arm 206 of the torsion spring 131 downward because the moment arm 206 is retained within the opening 248 of the radial protrusion 246 of the load block 240. Thus, the load block 240 and, more particularly, the radial protrusion 246 is an example of a means for pushing the moment arm 206 of the torsion spring 131. In some examples, the load block 240 is omitted and the load nut directly urges the moment arm 206 downwards. More particularly, in some such examples, the load nut 238 (or a corresponding load screw as noted above) includes a relatively large head (e.g., a circumferential flange) that overlaps the moment arm 206 such that, as the load nut 238 is tightened, the underside of the head of the load nut 238 engages with and pushes down on the moment arm 206. In other words, the large head of such a load nut 238 (or a similarly shaped load screw) is another example of a means for pushing the moment arm 206 of the torsion spring 131.

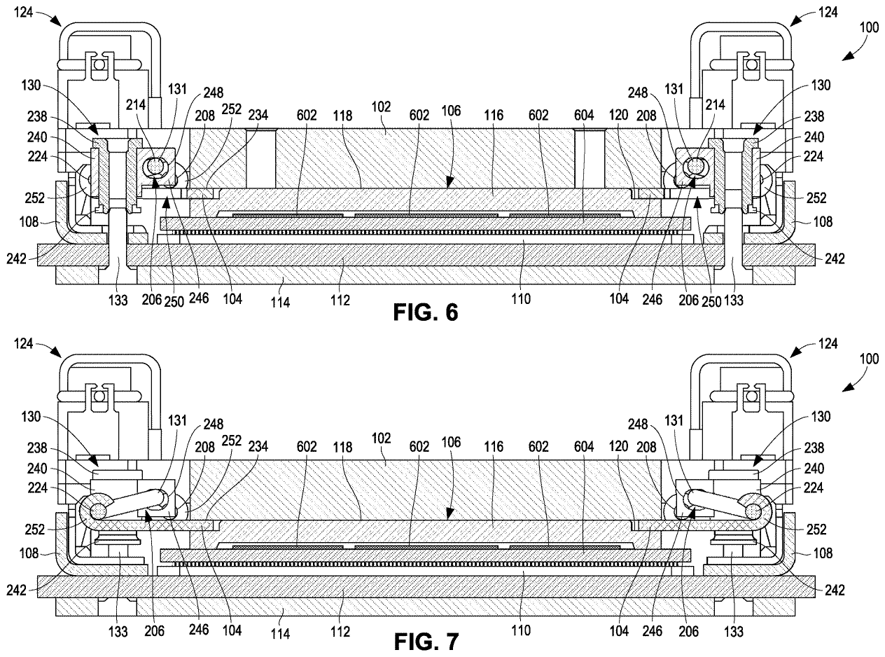

In some examples, the load plate 104 includes cutouts 250 aligned with the spring loading assemblies 132 to permit the free vertical movement of the spring loading assemblies 132 relative to the load plate 104. As noted above, the rest of the torsion spring 131 (e.g., the support sections 204 and the torsion segments 224) is located flat against the first surface 234 of the load plate 104. Thus, the downward force created by the tightening of the load nut 238 onto the third post 133 results in the moment arm 206 rotating relative to the torsion segments 224, thereby creating torque within the torsion segments 224. The torque in the torsion segments 224 is transferred to the support sections 204 to produce a downward force on the load plate 104 that, in turn, pushes down on the IC package 106. In this manner, a load force that is independent of the fasteners 124 on the heatsink is applied to the IC package 106. The movement of the spring loading assembly 132 and the resulting movement of the torsion spring 131 are discussed further below in connection with FIGS. 6-9.

In some examples, the support sections 204 and the torsion segments 224 of the torsion spring 131 are held in place against the first surface 234 of the load plate 104 via one or more braces 252 (e.g., retainers). In the illustrated example, the braces 252 are integral extensions (e.g., tabs or flanges) of the load plate 104 that have been bent or curled around different portions of the torsion spring 131. For instance, in this example, each torsion segment 224 is secured in place by two braces 252 and each support section 204 is secured in place by one additional brace 252. In other examples, different numbers of braces 252 can be used to secure the torsion spring. In some examples, the braces 252 can be in different locations and/or different sizes from what is shown in the illustrated example. In some examples, the braces 252 are bent around the torsion spring 131 after the torsion spring 131 is positioned against the load plate 104. As such, in some examples, once the braces 252 are bent around the torsion spring 131, it is not possible to remove the torsion spring 131 (without unbending the braces 252). In other examples, the braces 252 are bent with sufficient clearance for the torsion spring 131 to be selectively installed and removed as needed without the need for further bending.

In this example, the load plate 104 includes translation retainers 254 that function as mechanical stops at either end of the torsion spring 131. In this example, the translation retainers 254 are small integral extensions (e.g., tabs or flanges) of the load plate 104 that have been bent or curled to protrude above the first surface 234. In some examples, the translation retainers 254 may be implemented by additional braces 252. In some examples, one or more of the braces 252 may be implemented by translation retainers 254. In some examples, the braces 252 and/or the translation retainers 254 are omitted and/or other methods are used to secure the spring loading assembly 132 to the load plate 104. For instance, threaded fasteners, clips, adhesive, weldments, and/or other securing mechanisms that are not integral to the load plate 104 may also be used to secure the torsion spring 131 in place. Accordingly, the braces 252, the retainers 254, and the alternative securing mechanisms are all examples of means for securing the torsion spring 131 in place relative to the load plate 104.

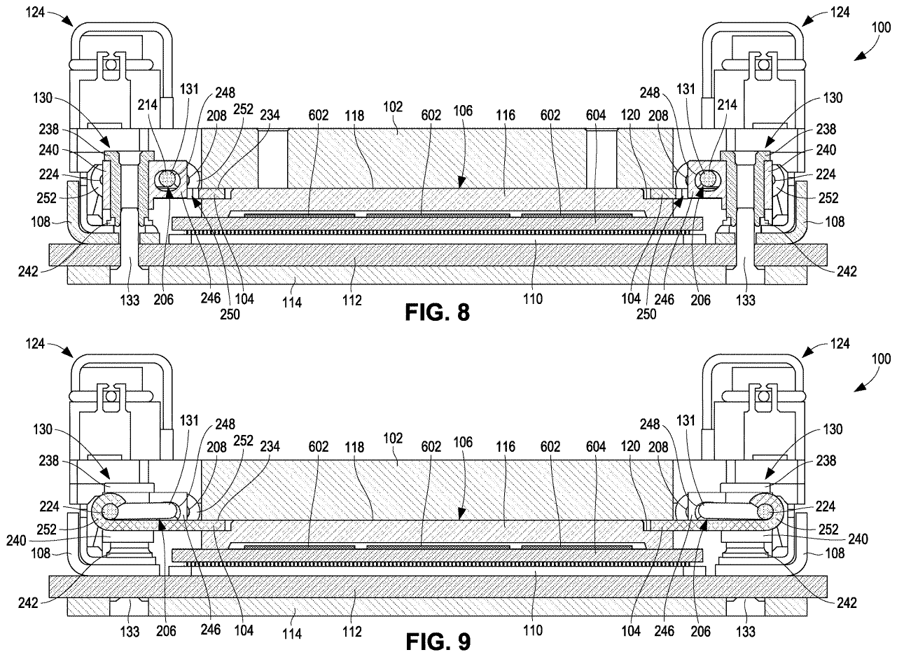

FIGS. 6 and 7 are cross-sectional views of the component stack 100 of FIG. 1 after assembly but before the example spring loading assemblies 132 have been tightened to apply a load on the load plate 104. FIGS. 8 and 9 are cross-sectional views similar to FIGS. 6 and 7 but showing the example component stack 100 of FIG. 1 after the example spring loading assemblies 132 have been tightened to apply a load on the load plate 104. The cross-section shown in FIGS. 6 and 8 is along a first plane extending directly through the spring loading assemblies 132. The cross-section shown in FIGS. 7 and 9 is along a second plane extending through the braces 252 immediately in front of (from the perspective shown) and closest to the spring loading assemblies 132.

In the illustrated example shown in FIGS. 6-9, the IC package 106 includes three semiconductor dies 602 mounted to a package substrate 604 and covered by the IHS 116. In other examples, the IC package 106 can have any other suitable number of semiconductor dies 602. In some examples, a first thermal interface material (TIM) is provided between the semiconductor dies 602 and the IHS 116. As shown in the illustrated example, the heatsink 102 interfaces with (e.g., is thermally coupled to) the central region 118 of the IHS 116. In some examples, a second TIM is provided between the heatsink 102 and the IHS 116. As discussed above, the IHS 116 includes a recessed shoulder 120 that is spaced apart from the heatsink 102. In this example, the load plate 104 extends into the gap between the recessed shoulder 120 and the heatsink 102 and rests on (e.g., engages with) the recessed shoulder 120. In some examples, the thickness of the load plate 104 is specified so that the first (upper) surface 234 of the load plate 104 is flush with or below the central region 118 of the IHS 116 so as not to affect engagement (and corresponding thermal coupling) of the heatsink 102 and the central region 118 of the IHS 116. In other examples, the underside of the heatsink 102 includes cutouts to accommodate space for the load plate 104 to extend above the central region 118 of the IHS 116.

As discussed above, in some examples, as the fasteners 124 on the heatsink 102 are tightened to the first posts 125 on the bolster plate 108, the heatsink 102 is urged downward (e.g., toward the PCB 112). At the same time, the backplate 114 (also coupled to the bolster plate 108) is urged upwards (e.g., also toward the PCB 112). Thus, the tightening of the fasteners 124 places the components in the stack 100 therebetween in compression. This compressive force urges the IC package 106 into engagement with the socket 110 to ensure reliable connections between contacts. The compressive force also ensures reliable thermal coupling between the heatsink 102 and the IC package 106. Due in part to the location of the fasteners 124 (located at the corners of the heatsink 102), the forces generated by the fasteners 124 can cause warpage, bending, or deflection in the backplate 114 that can deleteriously affect the reliable electrical coupling between the IC package 106 and the socket 110 at certain locations. Accordingly, in some examples, an independent loading mechanism is provided at a different location (e.g., away from the corners) on the IC package 106 by way of the torsion spring assemblies 130.

More particularly, as shown in FIGS. 6 and 7, the moment arms 206 of the torsion springs 131 extend upward at an angle relative to the first (upper) surface 234 of the load plate 104. By contrast, the first straight segments 208 and the torsion segments 224 (both of which are barely visible behind the spring loading assemblies 132 in FIGS. 6 and 7) rest on (are in contact with) the first (upper) surface 234 of the load plate 104. In the illustrated example of FIGS. 6 and 7, the spring loading assemblies 132 are supported above the third posts 133 extending up from the backplate 114 by the third straight segment 214 (labelled in FIG. 6) of the moment arm 206 extending through and engaging an upper surface of the opening 248 in the radial protrusion 246 of the load block 240. In some examples, the load nuts 238 of the spring loading assemblies 132 engage with the upper end of the third posts 133 before and/or at the same time as the upper surface of the opening 248 engages with moment arm 206 in the untightened state.

As noted above, FIGS. 8 and 9 correspond to the same cross-sectional views as FIGS. 6 and 7 except that the spring loading assemblies 132 of the torsion spring assemblies 130 have been tightened in FIGS. 8 and 9. Particularly, as shown in the illustrated example of FIGS. 8 and 9, the load nuts 238 of the spring loading assemblies 132 have been threaded down onto the third posts 133. As a result, the load blocks 240 (which move with the load nuts 238) push the moment arms 206 of the torsion springs 131 downward (e.g., toward the PCB 112). Inasmuch as the support sections 204 and the torsion segments 224 are already against the load plate 104, which is against the recessed shoulder 120, the support sections 204 and the torsion segments 224 cannot freely move downward with the moment arms 206. Instead, the moment arms 206 are forced to rotate about an axis defined by the torsion segments 224, thereby producing a torsion force within the torsion segments 224. The torsion force is transferred to the free ends of the support sections 204 (e.g., the first straight segments 208) that create a downward force on the load plate 104 that, in turn, urges the IC package 106 downward.

In the illustrated example of FIGS. 6 and 7, the bottom surface of the radial protrusion 246 of the load block 240 is above the first (upper) surface 234 of the load plate 104 with the lower portion of the load block 240 extending into the cutout 250 (labelled in FIG. 6) in the load plate 104. Once the spring loading assemblies 132 are tightened (as shown in FIGS. 8 and 9), the radial protrusion 246 extends into the cutout 250 without extending all the way therethrough. In other examples, the travel distance and/or beginning and ending points of the spring loading assemblies 132 as they move between a tightened position (FIGS. 8 and 9) and a loosened position (FIGS. 6 and 7) can be different from what is shown in the illustrated example. For instance, in some examples, the radial protrusion 246 extends into the cutout 250 even before the load nut 238 is tightened. Additionally or alternatively, in some examples, the radial protrusion 246 extends all the way through and below the bottom surface of the load plate 104 after the load nut 238 is tightened.

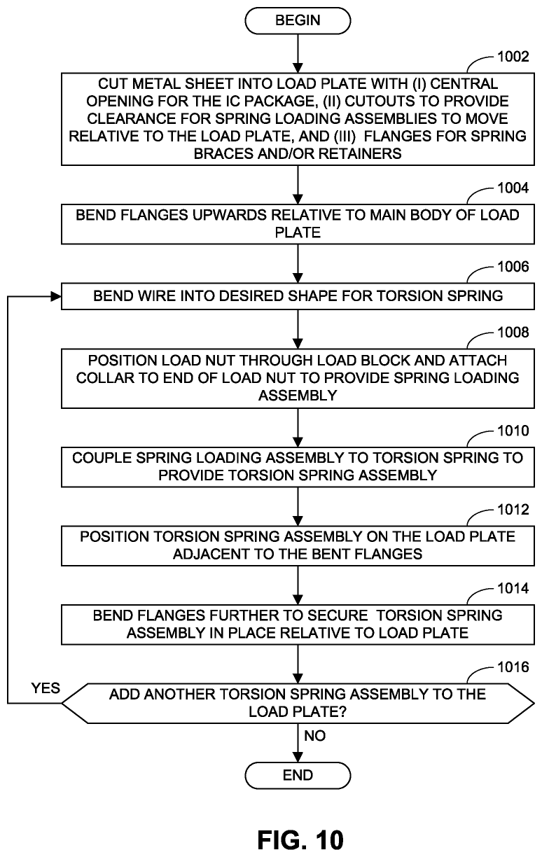

FIG. 10 is a flowchart representative of an example method of manufacturing the example load plate 104 with the torsion spring assemblies 130 of FIG. 1-9. In some examples, some or all of the operations outlined in the example method of FIG. 10 are performed automatically by fabrication equipment that is programmed to perform the operations. Although the example method of manufacture is described with reference to the flowchart illustrated in FIG. 10, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method of FIG. 10 begins at block 1002, which involves cutting a metal sheet to provide the load plate 104 with (i) a central opening 129 for the IC package 106, (ii) cutouts 136 to provide clearance for the spring loading assemblies 132 to move relative to the load plate 104, and (iii) flanges for spring braces 252 and/or retainers 254. In some examples, the metal sheet is selected to have a thickness that can fit between the recessed shoulder 120 of the IHS 116 of the IC package 106 and the heatsink 102. At block 1004, the example method involves bending the flanges upwards relative to the main body of the load plate 104. In this example, the flanges are only partially bent relative to their final position, which is completed later. In other examples, the flanges can be bent to their final position before proceeding.

At block 1006, the example method involves bending a wire (e.g., the wire 202) into a desired shape for the torsion spring 131. In some examples, the desired shape depends upon the particular load to be produced by the torsion spring assembly 130. In some examples, the shape is created so that as the moment arm 206 bends to produce a torque in the torsion segments 224, the wire 202 stays under a yield strength threshold. At block 1008, the example method involves positioning the load nut 238 through the load block 240 and attaching the collar 242 to the end of the load nut 238 to provide a spring loading assembly 132. At block 1010, the example method involves coupling the spring loading assembly to the torsion spring 131 (provided at block 1006). In some examples, some or all of the bends in the wire to shape the torsion spring 131 are implemented after coupling the spring loading assembly 132 to the wire. Further, in some examples, blocks 1006-1010 are performed before and/or in parallel with blocks 1002-1004.

At block 1012, the example method involves positioning the torsion spring assembly 130 on the load plate 104 adjacent to the bent flanges. At block 1012, the example method involves bending the flanges further to secure the torsion spring assembly 130 in place relative to the load plate 104. In some examples, all bending of the flanges is performed at block 1014 such that block 1004 may be omitted. In other examples, all bending of the wire is performed at block 1004 such that block 1014 may be omitted. At block 1016, the method involves determining whether to add another torsion spring assembly 130 to the load plate. If so, the method returns to block 1006. Otherwise, the example method of FIG. 10 ends.

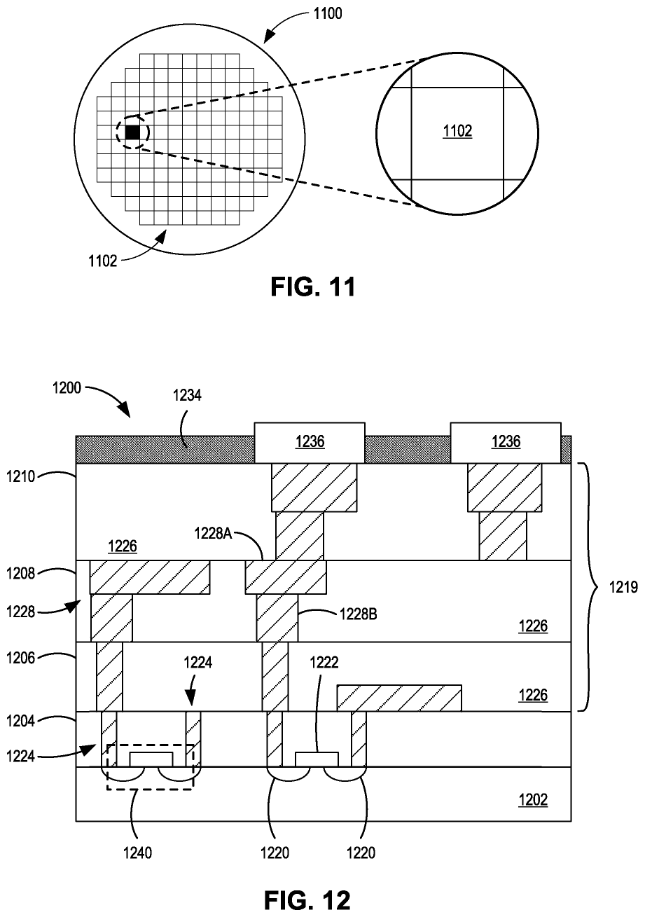

The example component stack 100 disclosed herein may be included in and/or associated with any suitable electronic component. FIGS. 11-15 illustrate various examples of apparatus that may include or be included in the example component stack 100 disclosed herein.

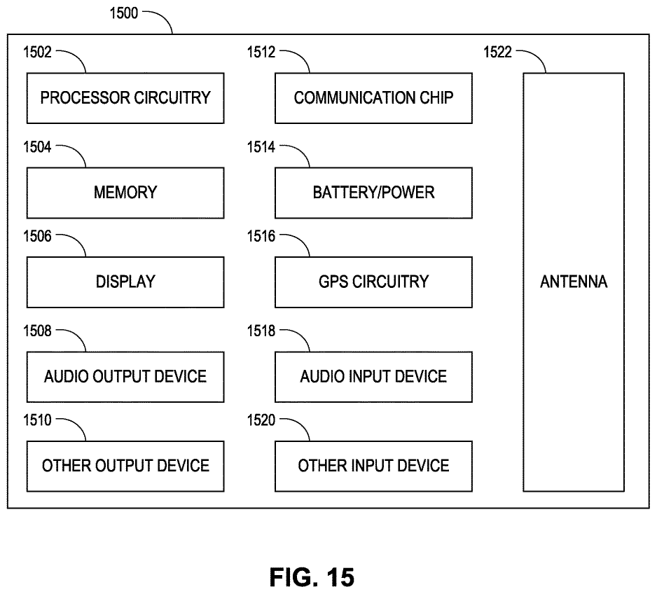

FIG. 11 is a top view of a wafer 1100 and dies 1102 that may be included in the IC package 106 of FIGS. 1 and 6-9 (e.g., as any suitable ones of the dies 602). The wafer 1100 includes semiconductor material and one or more dies 1102 having circuitry. Each of the dies 1102 may be a repeating unit of a semiconductor product. After the fabrication of the semiconductor product is complete, the wafer 1100 may undergo a singulation process in which the dies 1102 are separated from one another to provide discrete “chips.” The die 1102 includes one or more transistors (e.g., some of the transistors 1240 of FIG. 12, discussed below), supporting circuitry to route electrical signals to the transistors, passive components (e.g., traces, resistors, capacitors, inductors, and/or other circuitry), and/or any other components. In some examples, the die 1102 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 1102. For example, a memory array of multiple memory circuits may be formed on a same die 1102 as programmable circuitry (e.g., the processor circuitry 1502 of FIG. 15) and/or other logic circuitry. Such memory may store information for use by the programmable circuitry. The example IC package 106 disclosed herein may be manufactured using a die-to-wafer assembly technique in which some dies are attached to a wafer 1100 that includes others of the dies, and the wafer 1100 is subsequently singulated.

FIG. 12 is a cross-sectional side view of an IC device 1200 that may be included in the example IC package 106 (e.g., in any one of the dies 602). One or more of the IC devices 1200 may be included in one or more dies 1102 (FIG. 11). The IC device 1200 may be formed on a die substrate 1202 (e.g., the wafer 1100 of FIG. 11) and may be included in a die (e.g., the die 1102 of FIG. 11). The die substrate 1202 may be a semiconductor substrate including semiconductor materials including, for example, n-type or p-type materials systems (or a combination of both). The die substrate 1202 may include, for example, a crystalline substrate formed using a bulk silicon or a silicon-on-insulator (SOI) substructure. In some examples, the die substrate 1202 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an IC device 1200 may be used. The die substrate 1202 may be part of a singulated die (e.g., the dies 1102 of FIG. 11) or a wafer (e.g., the wafer 1100 of FIG. 11).

The IC device 1200 may include one or more device layers 1204 disposed on and/or above the die substrate 1202. The device layer 1204 may include features of one or more transistors 1240 (e.g., metal oxide semiconductor field-effect transistors (MOSFETs)) formed on the die substrate 1202. The device layer 1204 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1240 may include a gate 1222 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1240 along the source-channel-drain direction, the gate electrode may include a U-shaped structure that includes a bottom portion substantially parallel to the surface of the die substrate 1202 and two sidewall portions that are substantially perpendicular to the top surface of the die substrate 1202. In other examples, at least one of the metal layers that form the gate electrode may be a planar layer that is substantially parallel to the top surface of the die substrate 1202 and does not include sidewall portions substantially perpendicular to the top surface of the die substrate 1202. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of corresponding transistor(s) 1240. The S/D regions 1220 may be formed using an implantation/diffusion process or an etching/deposition process, for example. In the former process, dopants such as boron, aluminum, antimony, phosphorus, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some examples, the epitaxially deposited silicon alloy may be doped in situ with dopants such as boron, arsenic, or phosphorus. In some examples, the S/D regions 1220 may be formed using one or more alternate semiconductor materials such as germanium or a group III-V material or alloy. In further examples, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the IC device 1200.

The interconnect structures 1228 may be arranged within the interconnect layers 1206-1210 to route electrical signals according to a wide variety of designs (in particular, the arrangement is not limited to the particular configuration of interconnect structures 1228 depicted in FIG. 12). Although a particular number of interconnect layers 1206-1210 is depicted in FIG. 12, examples of the present disclosure include IC devices having more or fewer interconnect layers than depicted.

In some examples, the interconnect structures 1228 may include lines 1228a and/or vias 1228b filled with an electrically conductive material such as a metal. The lines 1228a may be arranged to route electrical signals in a plane that is substantially parallel with a surface of the die substrate 1202 upon which the device layer 1204 is formed. For example, the lines 1228a may route electrical signals in and/or out of the page from the perspective of FIG. 12. The vias 1228b may be arranged to route electrical signals in a plane that is substantially perpendicular to the surface of the die substrate 1202 upon which the device layer 1204 is formed. In some examples, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some examples, the dielectric material 1226 disposed between the interconnect structures 1228 in different ones of the interconnect layers 1206-1210 may have different compositions; in other examples, the composition of the dielectric material 1226 between different interconnect layers 1206-1210 may be the same.

A first interconnect layer 1206 (referred to as Metal 1 or “M1”) may be formed directly on the device layer 1204. In some examples, the first interconnect layer 1206 may include lines 1228a and/or vias 1228b, as shown. The lines 1228a of the first interconnect layer 1206 may be coupled with contacts (e.g., the S/D contacts 1224) of the device layer 1204.

A second interconnect layer 1208 (referred to as Metal 2 or “M2”) may be formed directly on the first interconnect layer 1206. In some examples, the second interconnect layer 1208 may include vias 1228b to couple the lines 1228a of the second interconnect layer 1208 with the lines 1228a of the first interconnect layer 1206. Although the lines 1228a and the vias 1228b are structurally delineated with a line within each interconnect layer (e.g., within the second interconnect layer 1208) for the sake of clarity, the lines 1228a and the vias 1228b may be structurally and/or materially contiguous (e.g., simultaneously filled during a dual-damascene process) in some examples.

A third interconnect layer 1210 (referred to as Metal 3 or “M3”) (and additional interconnect layers, as desired) may be formed in succession on the second interconnect layer 1208 according to similar techniques and/or configurations described in connection with the second interconnect layer 1208 or the first interconnect layer 1206. In some examples, the interconnect layers that are “higher up” in the metallization stack 1219 in the IC device 1200 (i.e., further away from the device layer 1204) may be thicker.

The IC device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to other external devices. For example, solder bonds may be formed on the one or more conductive contacts 1236 to mechanically and/or electrically couple a chip including the IC device 1200 with another component (e.g., a circuit board). The IC device 1200 may include additional or alternate structures to route the electrical signals from the interconnect layers 1206-1210; for example, the conductive contacts 1236 may include other analogous features (e.g., posts) that route the electrical signals to external components.

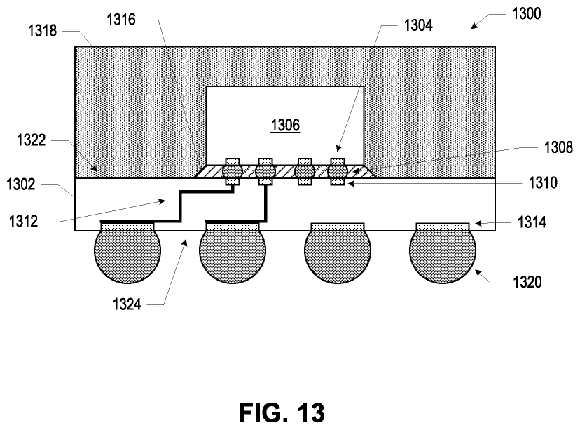

FIG. 13 is a cross-sectional view of an example IC package 1300 that may be used to implement the IC package 106 of FIGS. 1 and 6-9. The package substrate 1302 may include a dielectric material, and may have conductive pathways extending through the dielectric material between upper and lower faces 1322, 1324, and/or between different locations on the upper face 1322, and/or between different locations on the lower face 1324. These conductive pathways may take the form of any of the interconnects 1228 discussed above with reference to FIG. 12.

The IC package 1300 may include a die 1306 coupled to the package substrate 1302 via conductive contacts 1304 of the die 1306, first-level interconnects 1308, and conductive contacts 1310 of the package substrate 1302. The conductive contacts 1310 may be coupled to conductive pathways 1312 through the package substrate 1302, allowing circuitry within the die 1306 to electrically couple to various ones of the conductive contacts 1314 or to other devices included in the package substrate 1302, not shown. The first-level interconnects 1308 illustrated in FIG. 13 are solder bumps, but any suitable first-level interconnects 1308 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

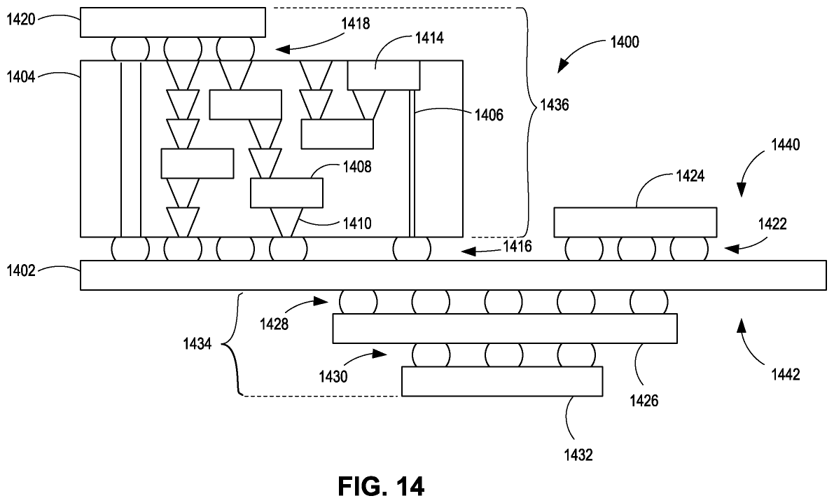

In some examples, an underfill material 1316 may be disposed between the die 1306 and the package substrate 1302 around the first-level interconnects 1308, and/or a mold compound 1318 may be disposed around the die 1306 and in contact with the package substrate 1302. In some examples, the underfill material 1316 may be the same as the mold compound 1318. Example materials that may be used for the underfill material 1316 and the mold compound 1318 are epoxy mold materials, as suitable. Second-level interconnects 1320 may be coupled to the conductive contacts 1314. The second-level interconnects 1320 illustrated in FIG. 13 are solder balls (e.g., for a ball grid array arrangement), but any suitable second-level interconnects 1320 may be used (e.g., pins in a pin grid array arrangement or lands in a land grid array arrangement). The second-level interconnects 1320 may be used to couple the IC package 1300 to another component, such as a circuit board (e.g., a motherboard), an interposer, or another IC package, as known in the art and as discussed below with reference to FIG. 14.

In FIG. 13, the IC package 1300 is a flip chip package. The die 1306 may take the form of any of the examples of the die 1102 discussed herein (e.g., may include any of the examples of the IC device 1200). Although the IC package 1300 illustrated in FIG. 13 is a flip chip package, other package architectures may be used. For example, the IC package 1300 may be a ball grid array (BGA) package, such as an embedded wafer-level ball grid array (eWLB) package. In another example, the IC package 1300 may be a wafer-level chip scale package (WLCSP) or a panel fanout (FO) package. Although a single die 1306 is illustrated in the IC package 1300 of FIG. 13, an IC package 1300 may include multiple dies 1306. An IC package 1300 may include additional passive components, such as surface-mount resistors, capacitors, and/or inductors disposed on the first face 1322 or the second face 1324 of the package substrate 1302. More generally, an IC package 1300 may include any other active and/or passive components known in the art.

FIG. 14 is a cross-sectional side view of an IC device assembly 1400 that may include the IC package 106 disclosed herein. In some examples, the IC device assembly corresponds to the IC package 106. The IC device assembly 1400 includes a number of components disposed on a circuit board 1402 (which may be, for example, a motherboard). The IC device assembly 1400 includes components disposed on a first face 1440 of the circuit board 1402 and an opposing second face 1442 of the circuit board 1402; generally, components may be disposed on one or both faces 1440 and 1442. Any of the IC packages discussed below with reference to the IC device assembly 1400 may take the form of the example IC package 106 of FIGS. 1 and 6-9.

In some examples, the circuit board 1402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1402. In other examples, the circuit board 1402 may be a non-PCB substrate.

The IC device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), male and female portions of a socket, an adhesive, an underfill material, and/or any other suitable electrical and/or mechanical coupling structure.

The package-on-interposer structure 1436 may include an IC package 1420 coupled to an interposer 1404 by coupling components 1418. The coupling components 1418 may take any suitable form for the application, such as the forms discussed above with reference to the coupling components 1416. Although a single IC package 1420 is shown in FIG. 14, multiple IC packages may be coupled to the interposer 1404; indeed, additional interposers may be coupled to the interposer 1404. The interposer 1404 may provide an intervening substrate used to bridge the circuit board 1402 and the IC package 1420. The IC package 1420 may be or include, for example, a die (the die 1102 of FIG. 11), an IC device (e.g., the IC device 1200 of FIG. 12), or any other suitable component. Generally, the interposer 1404 may spread a connection to a wider pitch or reroute a connection to a different connection. For example, the interposer 1404 may couple the IC package 1420 (e.g., a die) to a set of BGA conductive contacts of the coupling components 1416 for coupling to the circuit board 1402. In the example illustrated in FIG. 14, the IC package 1420 and the circuit board 1402 are attached to opposing sides of the interposer 1404; in other examples, the IC package 1420 and the circuit board 1402 may be attached to a same side of the interposer 1404. In some examples, three or more components may be interconnected by way of the interposer 1404.

In some examples, the interposer 1404 may be formed as a PCB, including multiple metal layers separated from one another by layers of dielectric material and interconnected by electrically conductive vias. In some examples, the interposer 1404 may be formed of an epoxy resin, a fiberglass-reinforced epoxy resin, an epoxy resin with inorganic fillers, a ceramic material, or a polymer material such as polyimide. In some examples, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through-silicon vias (TSVs) 1406. The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The IC device assembly 1400 may include an IC package 1424 coupled to the first face 1440 of the circuit board 1402 by coupling components 1422. The coupling components 1422 may take the form of any of the examples discussed above with reference to the coupling components 1416, and the IC package 1424 may take the form of any of the examples discussed above with reference to the IC package 1420.

The IC device assembly 1400 illustrated in FIG. 14 includes a package-on-package structure 1434 coupled to the second face 1442 of the circuit board 1402 by coupling components 1428. The package-on-package structure 1434 may include a first IC package 1426 and a second IC package 1432 coupled together by coupling components 1430 such that the first IC package 1426 is disposed between the circuit board 1402 and the second IC package 1432. The coupling components 1428, 1430 may take the form of any of the examples of the coupling components 1416 discussed above, and the IC packages 1426, 1432 may take the form of any of the examples of the IC package 1420 discussed above. The package-on-package structure 1434 may be configured in accordance with any of the package-on-package structures known in the art.

FIG. 15 is a block diagram of an example electrical device 1500 that may include one or more of the example component stack 100 of FIGS. 1 and 6-9. For example, any suitable ones of the components of the electrical device 1500 may include one or more of the device assemblies 1400, IC devices 1200, or dies 1102 disclosed herein, and may be arranged in the example component stack 100. A number of components are illustrated in FIG. 15 as included in the electrical device 1500, but any one or more of these components may be omitted or duplicated, as suitable for the application. In some examples, some or all of the components included in the electrical device 1500 may be attached to one or more motherboards. In some examples, some or all of these components are fabricated onto a single system-on-a-chip (SoC) die.

Additionally, in various examples, the electrical device 1500 may not include one or more of the components illustrated in FIG. 15, but the electrical device 1500 may include interface circuitry for coupling to the one or more components. For example, the electrical device 1500 may not include a display 1506, but may include display interface circuitry (e.g., a connector and driver circuitry) to which a display 1506 may be coupled. In another set of examples, the electrical device 1500 may not include an audio input device 1518 (e.g., microphone) or an audio output device 1508 (e.g., a speaker, a headset, earbuds, etc.), but may include audio input or output device interface circuitry (e.g., connectors and supporting circuitry) to which an audio input device 1518 or audio output device 1508 may be coupled.

The electrical device 1500 may include programmable circuitry 1502 (e.g., one or more processing devices). The programmable circuitry 1502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1500 may include a memory 1504, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1504 may include memory that shares a die with the programmable circuitry 1502. This memory may be used as cache memory and may include embedded dynamic random access memory (eDRAM) or spin transfer torque magnetic random access memory (STT-MRAM).

In some examples, the electrical device 1500 may include a communication chip 1512 (e.g., one or more communication chips). For example, the communication chip 1512 may be configured for managing wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1512 may operate in accordance with other wireless protocols in other examples. The electrical device 1500 may include an antenna 1522 to facilitate wireless communications and/or to receive other wireless communications (such as AM or FM radio transmissions).

In some examples, the communication chip 1512 may manage wired communications, such as electrical, optical, or any other suitable communication protocols (e.g., the Ethernet). As noted above, the communication chip 1512 may include multiple communication chips. For instance, a first communication chip 1512 may be dedicated to shorter-range wireless communications such as Wi-Fi or Bluetooth, and a second communication chip 1512 may be dedicated to longer-range wireless communications such as global positioning system (GPS), EDGE, GPRS, CDMA, WiMAX, LTE, EV-DO, or others. In some examples, a first communication chip 1512 may be dedicated to wireless communications, and a second communication chip 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display 1506 (or corresponding interface circuitry, as discussed above). The display 1506 may include any visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any device that generates an audible indicator, such as speakers, headsets, or earbuds.

The electrical device 1500 may include an audio input device 1518 (or corresponding interface circuitry, as discussed above). The audio input device 1518 may include any device that generates a signal representative of a sound, such as microphones, microphone arrays, or digital instruments (e.g., instruments having a musical instrument digital interface (MIDI) output).

The electrical device 1500 may include GPS circuitry 1516. The GPS circuitry 1516 may be in communication with a satellite-based system and may receive a location of the electrical device 1500, as known in the art.

The electrical device 1500 may include any other output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include any other input device 1520 (or corresponding interface circuitry, as discussed above). Examples of the other input device 1520 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1500 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide a loading mechanism for an IC package heat dissipating component stack that functions independent of the loading mechanism (e.g., fasteners) on the heatsink. More particularly, examples disclosed herein implement torsion spring assemblies operatively coupled to a load plate that is to be positioned between the heatsink and an IC package in a component stack. As the torsion springs in the torsion spring assemblies are torqued, a reactionary force urges the load plate toward the IC package, thereby providing a loading force that is independent of the heatsink loading mechanism. The torsion springs in disclosed examples enable load forces on an IC package to be tuned at a lower spring constant with a longer load path. As a result, examples disclosed herein provide for better compensation for tolerance in other parts of the loading path. Furthermore, example torsion spring assemblies can be implemented as an independent sub-assembly that does not need to be designed as part of the thermal solution associated with the heat sink.

Further examples and combinations thereof include the following:

Example 1 includes an apparatus comprising a load plate to interface with an integrated circuit package along a perimeter of the integrated circuit package while permitting a heatsink to interface with a central region of the integrated circuit package, and a torsion spring carried by the load plate, the torsion spring on a first surface of the load plate, the integrated circuit package to engage a second surface of the load plate, the second surface opposite the first surface, the torsion spring to urge the load plate toward the integrated circuit package to provide a load to urge the integrated circuit package toward a socket on a circuit board.

Example 2 includes the apparatus of example 1, wherein the torsion spring includes a wire having a shape that includes a moment arm, a torsion segment, and a support section, the torsion segment between the moment arm and the support section, the torsion segment and the support section in a plane aligned with the first surface of the load plate, the moment arm angled relative to the plane in a direction away from the first surface of the load plate.

Example 3 includes the apparatus of example 2, wherein the torsion segment is a first torsion segment, and the support section is a first support section, the torsion spring including a second torsion segment and a second support section, the second torsion segment between the moment arm and the second support section, the moment arm between the first torsion segment and the second torsion segment.

Example 4 includes the apparatus of example 3, wherein the first torsion segment is aligned with the second torsion segment.

Example 5 includes the apparatus of any one or more of examples 2-4, including a first brace to hold the torsion segment adjacent to the first surface of the load plate, and a second brace to hold the support section adjacent to the first surface of the load plate.

Example 6 includes the apparatus of example 5, wherein at least one of the first brace or the second brace is an integral extension of the load plate that is bent around the corresponding torsion segment or support section.

Example 7 includes the apparatus of any one or more of examples 2-6, including at least one retainer protruding away from the first surface of the load plate to block translation of the load plate along the plane.

Example 8 includes the apparatus of any one or more of examples 1-7, wherein the integrated circuit package includes a shoulder along the perimeter of the integrated circuit package that is recessed relative to the central region of the integrated circuit package, the load plate to engage the shoulder.

Example 9 includes the apparatus of any one or more of examples 1-8, including a spring loading assembly to produce a torque in the torsion spring as the spring loading assembly moves relative to the load plate in a direction transverse to the first surface and towards the circuit board, the torque to cause the torsion spring to urge the load plate toward the integrated circuit package.

Example 10 includes the apparatus of example 9, wherein movement of the spring loading assembly is controlled by threaded engagement between the spring loading assembly and at least one of a post or a hole in at least one of a bolster plate or a backplate.

Example 11 includes the apparatus of any one or more of examples 9-10, wherein the spring loading assembly includes a load nut to be threaded onto a post extending from at least one of a bolster plate or a backplate, the post to extend adjacent to the integrated circuit package in a direction transverse to the first surface of the load plate, the load nut to force a moment arm of the torsion spring toward the load plate when the load nut is threaded onto the post.

Example 12 includes the apparatus of example 11, including a load block operatively coupled between the load nut and the moment arm of the torsion spring, the load nut extending through a hole in the load block, the load block including a protrusion that at least partially surrounds the moment arm of the torsion spring.

Example 13 includes the apparatus of example 12, wherein the spring loading assembly includes a collar to be attached to an end of the load nut to retain the load nut in the hole of the load block.

Example 14 includes the apparatus of any one or more of examples 9-13, wherein the load plate includes a cutout to provide clearance for the spring loading assembly to extend through the load plate as the spring loading assembly moves relative to the load plate.

Example 15 includes an apparatus comprising an integrated circuit package, a socket on a first side of a circuit board, the socket to receive the integrated circuit package, a backplate on a second side of the circuit board opposite the first side, a heatsink including fasteners to urge the backplate and the heatsink towards each other to apply a first force urging the integrated circuit package toward the socket, a load plate between the heatsink and a periphery of the integrated circuit package, and a torsion spring assembly to generate a second force to urge the integrated circuit package toward the socket, the second force generated independent of the fasteners of the heatsink.

Example 16 includes the apparatus of example 15, wherein the torsion spring assembly is to generate the second force at a location closer to a center of the integrated circuit package than the fasteners are to the center of the integrated circuit package.

Example 17 includes the apparatus of any one or more of examples 15-16, wherein the torsion spring assembly includes a torsion spring and a spring loading assembly to load the torsion spring as threads on the spring loading assembly are engaged with at least one of (i) threads on a post coupled to the backplate or (ii) a threaded hole in at least one of the backplate or a bolster plate coupled to the backplate, the second force corresponding to a reactionary force to the loading of the torsion spring.

Example 18 includes an apparatus comprising means for engaging with a surface of an integrated circuit package, the surface to face away from a socket, and means for urging the means for engaging towards the surface of the integrated circuit package by a first loading force, the first loading force independent of a second loading force from a heatsink to urge against the integrated circuit package.

Example 19 includes the apparatus of example 18, wherein the means for urging includes a means for storing torque, and means for loading the means for storing torque, the first loading force corresponding to a reactionary force to a torque stored in the means for storing torque.

Example 20 includes the apparatus of example 19, wherein the means for loading includes means for threading, and means for pushing a moment arm of the means for storing torque.

Example 21 includes the apparatus of any one or more of examples 18-20, including means for securing the means for storing torque in place relative to the means for engaging.

Example 22 includes a method comprising fabricating a load plate with an opening for an integrated circuit package, the load plate to engage a surface of the integrated circuit package, the surface to face away from a socket that is to receive the integrated circuit package, coupling a spring loading assembly to a torsion spring, and securing the torsion spring in place relative to the load plate, the spring loading assembly to be moveable relative to the load plate to generate a torque in the torsion spring to urge the integrated circuit package toward the socket.

Example 23 includes the method of example 22, including fabricating the spring loading assembly by positioning at least one of a load nut or a load screw through in a load block, and attaching a collar to an end of the least one of the load nut or the load screw.

Example 24 includes the method of example 23, wherein the load block includes a radial protrusion with an opening extending therethrough, and the coupling of the spring loading assembly to the torsion spring includes positioning the torsion spring within the opening.

Example 25 includes the method of any one or more of examples 22-24, wherein the fabricating of the load plate includes providing a cutout in the load plate to provide clearance for the spring loading assembly to move relative to the load plate.

Example 26 includes the method of any one or more of examples 22-25, wherein the fabricating of the load plate includes providing flanges, and the securing of the torsion spring relative to the load plate includes bending the flanges to wrap around the torsion spring.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a load plate to interface with an integrated circuit package along a perimeter of the integrated circuit package while permitting a heatsink to interface with a central region of the integrated circuit package; and
a torsion spring carried by the load plate, the torsion spring on a first surface of the load plate, the integrated circuit package to engage a second surface of the load plate, the second surface opposite the first surface, the torsion spring to urge the load plate toward the integrated circuit package to provide a load to urge the integrated circuit package toward a socket on a circuit board.

2. The apparatus of claim 1, wherein the torsion spring includes a wire having a shape that includes a moment arm, a torsion segment, and a support section, the torsion segment between the moment arm and the support section, the torsion segment and the support section in a plane aligned with the first surface of the load plate, the moment arm angled relative to the plane in a direction away from the first surface of the load plate.

3. The apparatus of claim 2, wherein the torsion segment is a first torsion segment, and the support section is a first support section, the torsion spring including a second torsion segment and a second support section, the second torsion segment between the moment arm and the second support section, the moment arm between the first torsion segment and the second torsion segment.

4. The apparatus of claim 3, wherein the first torsion segment is aligned with the second torsion segment.

5. The apparatus of claim 2, including:
a first brace to hold the torsion segment adjacent to the first surface of the load plate; and
a second brace to hold the support section adjacent to the first surface of the load plate.

6. The apparatus of claim 5, wherein at least one of the first brace or the second brace is an integral extension of the load plate that is bent around the corresponding torsion segment or support section.

7. The apparatus of claim 2, including at least one retainer protruding away from the first surface of the load plate to block translation of the load plate along the plane.

8. The apparatus of claim 1, wherein the integrated circuit package includes a shoulder along the perimeter of the integrated circuit package that is recessed relative to the central region of the integrated circuit package, the load plate to engage the shoulder.

9. The apparatus of claim 1, including a spring loading assembly to produce a torque in the torsion spring as the spring loading assembly moves relative to the load plate in a direction transverse to the first surface and towards the circuit board, the torque to cause the torsion spring to urge the load plate toward the integrated circuit package.

10. The apparatus of claim 9, wherein movement of the spring loading assembly is controlled by threaded engagement between the spring loading assembly and at least one of a post or a hole in at least one of a bolster plate or a backplate.

11. The apparatus of claim 9, wherein the spring loading assembly includes a load nut to be threaded onto a post extending from at least one of a bolster plate or a backplate, the post to extend adjacent to the integrated circuit package in a direction transverse to the first surface of the load plate, the load nut to force a moment arm of the torsion spring toward the load plate when the load nut is threaded onto the post.

12. The apparatus of claim 11, including a load block operatively coupled between the load nut and the moment arm of the torsion spring, the load nut extending through a hole in the load block, the load block including a protrusion that at least partially surrounds the moment arm of the torsion spring.

13. The apparatus of claim 12, wherein the spring loading assembly includes a collar to be attached to an end of the load nut to retain the load nut in the hole of the load block.

14. The apparatus of claim 9, wherein the load plate includes a cutout to provide clearance for the spring loading assembly to extend through the load plate as the spring loading assembly moves relative to the load plate.

15. An apparatus comprising:
an integrated circuit package;
a socket on a first side of a circuit board, the socket to receive the integrated circuit package;
a backplate on a second side of the circuit board opposite the first side;
a heatsink including fasteners to urge the backplate and the heatsink towards each other to apply a first force urging the integrated circuit package toward the socket;
a load plate between the heatsink and a periphery of the integrated circuit package; and
a torsion spring assembly to generate a second force to urge the integrated circuit package toward the socket, the second force generated independent of the fasteners of the heatsink.

16. The apparatus of claim 15, wherein the torsion spring assembly is to generate the second force at a location closer to a center of the integrated circuit package than the fasteners are to the center of the integrated circuit package.

17. The apparatus of claim 15, wherein the torsion spring assembly includes a torsion spring and a spring loading assembly to load the torsion spring as threads on the spring loading assembly are engaged with at least one of (i) threads on a post coupled to the backplate or (ii) a threaded hole in at least one of the backplate or a bolster plate coupled to the backplate, the second force corresponding to a reactionary force to the loading of the torsion spring.

18. An apparatus comprising:
means for engaging with a surface of an integrated circuit package, the surface to face away from a socket; and
means for urging the means for engaging towards the surface of the integrated circuit package by a first loading force, the first loading force independent of a second loading force from a heatsink to be urged against the integrated circuit package.

19. The apparatus of claim 18, wherein the means for urging includes:
a means for storing torque; and
means for loading the means for storing torque, the first loading force corresponding to a reactionary force to a torque stored in the means for storing torque.

20. The apparatus of claim 19, wherein the means for loading includes:
means for threading; and
means for pushing a moment arm of the means for storing torque.
